(19) United States
(12) Patent Application Publication
(10) Pub. No.: US 2024/0237300 A9
(43) Pub. Date: Jul. 11, 2024

(54) ENVIRONMENTALLY HARDENED COLD PLATE FOR USE IN LIQUID COOLING OF ELECTRONIC DEVICES

(71) Applicant: STRATEGIC THERMAL LABS, LLC, GEORGETOWN, TX (US)

(72) Inventor: AUSTIN MICHAEL SHELNUTT, GEORGETOWN, TX (US)

(21) Appl. No.: 18/493,680

(22) Filed: Oct. 24, 2023

Related U.S. Application Data
(60) Provisional application No. 63/418,932, filed on Oct. 24, 2022.
(60) Provisional application No. 63/418,938, filed on Oct. 24, 2022.

(51) Int. Cl. H05K 7/20

(52) U.S. Cl. CPC H05K 7/20763; H05K 7/20427

(57) ABSTRACT

A cold plate assembly has a cold plate that is resistant to corrosion and particulate fouling, allowing direct use of facility-grade cooling liquid and omission of a secondary coolant loop that uses a purified liquid coolant. The cold plate has a surface configured with an array of extended fins coated with at least one of a hydrophobic, non-conductive, and/or anti-corrosive surface treatment. The coated extended fins provide heat transfer directly to the cooling liquid without requiring a secondary coolant loop and without causing corrosion or clogging due to facility liquid chemical contaminants or particulates. An encapsulating lid of the cold plate assembly attaches to a perimeter of the surface encompassing the array of extended fins to form a liquid cooling cavity. The encapsulating lid has input and output ports sealably connectable by an open-loop liquid distribution system, respectively, to a facility liquid supply and return.

### CROSS-REFERENCE TO RELATED APPLICATIONS

The present application claims the benefit under 35 U.S.C. § 119 of the following U.S. Provisional Patent Applications all filed on 24 Oct. 2022: (i) Ser. No. 63/418,932 entitled “Environmentally Hardened Cold Plate for Use in Liquid Cooling with Suboptimal Water Quality”; and (ii) Ser. No. 63/418,938 entitled “Smart Rack Liquid Manifold”, the disclosures of which are hereby incorporated by reference in their entirety.

### BACKGROUND

### 1. Technical Field

The present application relates generally to heat transfer mechanisms used for cooling electronic devices, and more particularly, to liquid cooling apparatuses for removing heat generated by one or more electronic devices.

### 2. Description of the Related Art

Recent trends in global digital transformation have created incredible demand for increased processing performance in colocation and edge deployments of data/information processing servers. Datacenters today rely upon high power microprocessor devices, such as central processors (CPUs) and graphic processing units (GPUs), which generate a high level of heat in a small area. Traditional use of air as the heat transfer medium to cool heat dissipating components is unable to meet the thermal dissipation requirement of these high power microprocessor devices. Thus, liquid cooling using cold plates have become a preferred way to provide the required cooling. Cold plates are a type of heatsink that allows for a liquid coolant to be brought into thermal conduction contact with the heat-generating electronic components of servers and other information processing systems. These cold plates rely upon ultra-narrow fluid passages called “microchannels” to dissipate heat from the processors into the liquid coolant. The microchannels typically have hydraulic diameters of less than 1-mm and are with fin spacing that are 0.2-0.4-mm. With such small fin spacings, problems related to fin fouling can occur due to fin surface corrosion and solid particulate build-up within the microchannels. Microchannels that get plugged by contaminated water or by surface corrosion growth can no longer be utilized for heat transfer and the cold plate decreases in cooling efficacy.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 presents a three-dimensional disassembled view of a cold plate assembly and a heat generating electronic component, the cold plate assembly including an encapsulating lid and a cold plate with an array of extended fins that are coated to enable use with a facility liquid supply as the cooling liquid, according to one or more embodiments;

FIG. 2 is a three-dimensional view of the cold plate assembly attached to the heat generating electronic component of FIG. 1, according to one or more embodiments;

FIG. 3 is a side cutaway view of the cold plate assembly attached to the heat generating electronic component of FIG. 1 and presenting one coated fin extended in the direction of the cooling liquid flow, according to one or more embodiments;

FIG. 4 is a front cutaway view of the cold plate assembly attached to the heat generating electronic component of FIG. 1 and showing the protective coating on each of the array of extended fins and the intervening channels between adjacent fins, according to one or more embodiments;

FIG. 5 is a diagram of an information processing system including the heat generating electronic component with attached cold plate assembly of FIG. 1 as part of a liquid cooling system that includes an open-loop liquid distribution system, according to one or more embodiments;

FIG. 6 is a diagram of a first example liquid cooling system that supports a datacenter equipment center with rack-level liquid cooling of heat generating electronic components each utilizing an attached one of the environmentally hardened cold plate assembly of FIG. 1, utilizing one liquid cooling loop for heat exchange, according to one or more embodiments;

FIG. 7 is a diagram of a first example liquid cooling system that supports a datacenter equipment center with rack-level liquid cooling of heat generating electronic components utilizing an attached one of the cold plate assembly of FIG. 1, with four separated liquid cooling loops for heat exchange, according to one or more embodiments;

FIG. 8 is a diagram of a first example liquid cooling system that supports a datacenter equipment center with rack-level liquid cooling of heat generating electronic components utilizing an attached one of the cold plate assembly of FIG. 1, with three separated liquid cooling loops for heat exchange, according to one or more embodiments;

FIG. 9 illustrates a physical vapor deposition (PVD) process for covering a cold plate with a protective coating, which protects the cold plate from damage, deterioration, and/or clogging due to exposure to facility-grade cooling liquids, according to one or more embodiments;

FIG. 10 is a detailed view of the cold plate of FIG. 9 having a single layer coating deposited by PVD that includes three different elements respectively having hydrophobic, nonconductive, and anti-corrosion properties, according to one or more embodiments;

FIG. 11 is a detailed view of an alternate cold plate having a dual layer coating deposited by repeated PVD to provide two or more of the protective properties, according to one or more embodiments;

FIG. 12 is a flow diagram presenting a method of manufacturing a cold plate with surface coating that protects the cold plate fins and microchannels from damage, rusting and/or clogging while directly using facility liquid for liquid cooling of heat generating electronic components, according to one or more embodiments; and

FIG. 13 is a flow diagram presenting a method of using a cold plate assembly with the interior surface coated with a non-conductive, anti-corrosive (NCAC) coating, according to one or more embodiments.

### DETAILED DESCRIPTION

The present disclosure provides a cold plate assembly having a chemically coated cold plate, a liquid cooling system including the cold plate assembly, and a method of manufacturing the cold plate and cold plate assembly. The cold plate assembly enables liquid cooling of a heat generating component using direct facility (or facility-grade) cooling water in a single cooling loop, without causing deterioration or reduced efficacy of the cold plate due to corrosion or clogging from exposure to the chemical contaminants and/or solid particulates within the facility water. According to one aspect of the present disclosure, a cold plate is formed of a thermally conductive material, having a first surface attachable to a heat generating electronic component of an information processing system. The cold plate has a second surface opposed to the first surface and configured with an array of extended fins. Exterior surfaces of the extended fins and intervening channels are coated with at least one of a hydrophobic, a non-conductive, and an anti-corrosive surface treatment. The coated extended fins and intervening microchannels support use of facility-grade cooling liquid and provide heat transfer directly to the cooling liquid without requiring a secondary coolant loop and without causing corrosion or clogging due to cooling liquid particulates or chemical contaminants. An encapsulating lid of the cold plate assembly is attachable to the second surface and encompasses at least the array of extended fins to form a liquid cooling cavity. The encapsulating lid comprises an intake port and an exhaust port for coupling to a facility liquid supply and return. In addition to portions of the cold plate that cooperate with the encapsulating lid to form the liquid cooling cavity, the interior surface of the encapsulating lid is made of (or coated with) a material that is also hydrophobic, non-conductive, and an anti-corrosive.

According to a second aspect of the present disclosure, a liquid cooling system includes the cold plate assembly and includes an open-loop liquid distribution system. The liquid distribution system is sealably connected to and in fluid communication between the intake port of the cold plate assembly and a cooling liquid source to receive unheated cooling liquid and between the exhaust port of the cold plate assembly and a cooling liquid return to exhaust heated cooling liquid to the cooling liquid source or associated return container. The cooling liquid source may be a pressurized tap water source, a water cooling tower, a liquid storage container with gravity or pumped pressure, or other source.

According to a third aspect of the present disclosure, a method is provided of manufacturing a cold plate that supports use of direct facility-grade cooling liquid for liquid cooling of heat generating electronic components. In one or more embodiments, the method includes applying a coating of at least one of a hydrophobic, a non-conductive, and an anti-corrosive surface treatment to an exterior surface of an array of extended fins and intervening channels configured on a second surface of a cold plate formed from a thermally conductive material. The coating supports direct use of facility-grade cooling liquid to provide liquid transfer of heat by the facility liquid from a heat generating component to which the cold plate is attached, without requiring a secondary coolant loop and without causing corrosion or clogging of the cold plate due to cooling liquid chemical composition or solid particulates. In one or more embodiments, the method further includes sealably attaching an encapsulating lid to the second surface of the cold plate, encompassing at least the array of extended fins, the encapsulating lid forming a liquid cooling cavity. The encapsulating lid also includes an intake port and an exhaust port for coupling to a facility liquid supply and return. In one or more embodiments, the method further includes attaching a first surface, which is opposed to the second surface of the cold plate with the extended fins, to a heat generating electronic component of an information processing system.

According to a fourth aspect of the present disclosure, a method is provided for using a cold plate having an array of fins that have a non-conductive, anti-corrosive (NCAC) coating. In one or more embodiments, the method includes sealably coupling a supply port of an encapsulating lid of the cold plate directly to a cooling liquid source of unheated facility liquid. The method includes sealably coupling a return port of the encapsulating lid directly to a facility return to exhaust heated facility liquid from the cold plate. The method includes activating a supply valve to cause the flow of facility liquid through the cold plate, which receives the unheated facility liquid to provide liquid based cooling of a heat generating electronic component attached to the cold plate and exhausts heated facility liquid back to the cooling liquid source or a cooling liquid return (e.g., a separate return container from the cooling liquid source). In an example, returned cooling liquid may be drained away or may be processed for subsequent use as cooling liquid.

According to a fifth aspect of the present disclosure, an information processing system includes a heat generating electronic component. The information processing system includes a cold plate assembly attached to the heat generating electronic component via a first surface of a cold plate. The cold plate includes an opposed second surface configured with an array of extended fins having exterior surfaces that are coated with at least one of a hydrophobic, a non-conductive, and an anti-corrosive surface treatment. The extended fins support use of facility-grade cooling liquid and provide heat transfer directly to the cooling liquid without requiring a secondary coolant loop and without causing corrosion or clogging due to facility liquid particulates or chemical contaminants.

One of the challenges with using cold plates to provide liquid cooling of electronic components within a data center or server rack is the need for use of a complex system of multiple loops of cooling liquid dues to the sensitive nature of the cold plate, which is susceptible to corrosion and clogging if exposed to a flow of regular liquid. During liquid cooling, the applied liquid flows through the microchannels between the heated fins of the cold plate to absorb the heat being conducted from the attached heat generating component. In order to prevent these microchannels and the fins from fouling due to corrosion or from solid particulate within the cooling liquid, cold plate solution providers generally require the use of tightly controlled secondary coolant with optimized chemical properties to inhibit corrosion and prevent biological growth, and which has been filtered of fluid-borne particulate. The secondary coolant, which is referred to as a technology coolant supply (TCS) flows through a loop of conduits that is coupled to the less tightly controlled facility water supply (FWS) via a liquid-to-liquid heat exchanger, typically housed within a coolant distribution unit (CDU). The CDU effectively isolates the cold plates from hazardous water quality. In addition to cost and complexity of implementation, one additional penalty or drawback of this multi-loop system is the fluid temperature gradient between the FWS and the TCS. This temperature gradient, which is sometimes called the “approach temperature”, demands, according to thermodynamic laws, that the TCS always be warmer than the FWS when cooling information processing systems. This temperature gradient creates energy inefficiencies by forcing the FWS temperatures to have to be lowered so that the TCS temperatures stay within the specification of the microprocessor cold plate. This can limit cooling capacity of the achievable power utilization effectiveness (PUE) of the cooling solution. The present disclosure overcomes these deficiencies in the existing liquid cooling solutions by providing/manufacturing a cold plate and a corresponding cold plate assembly and liquid cooling system that are resistive to the fouling from direct exposure to facility water and thus enables the data center cooling solution to be provided with a single cooling loop utilizing the facility water supply.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical, and other changes may be made without departing from the spirit or scope of the present disclosure. The following detailed description is, therefore, not to be taken in a limiting sense, and the scope of the present disclosure is defined by the appended claims and equivalents thereof. Within the descriptions of the different views of the figures, similar elements are provided similar names and reference numerals as those of the previous figure(s). The specific numerals assigned to the elements are provided solely to aid in the description and are not meant to imply any limitations (structural or functional or otherwise) on the described embodiment. It will be appreciated that for simplicity and clarity of illustration, elements illustrated in the figures have not necessarily been drawn to scale. For example, the dimensions of some of the elements are exaggerated relative to other elements.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that term is utilized. As a specific example, reference is made herein to the term facility liquid, facility water, facility cooling liquid, facility-grade cooling liquid, and cooling liquid. It is appreciated that the terms facility liquid or facility cooling liquid are utilized to provide a specific example of a cooling liquid supplied by/at a datacenter facility in which the heat generating electronic components are operating and being cooled in a single liquid cooling loop that includes facility liquid, which is typically unpurified water. Facility-grade cooling liquid is a more general term that can apply to both cooling liquid that is being provided at a datacenter facility or any other cooling liquid that can contain contaminants and particulates, similar to the normal facility liquid found in datacenters. Thus, facility-grade cooling liquid can apply to any type of liquid, regardless of the source of the liquid, and can also apply to liquid cooling that is not provided at a “facility” or datacenter. The descriptions herein are meant to apply to any type of facility-grade cooling liquid. Additionally, it is appreciated that the cooling liquid utilized within the cooling loop that includes the described cold plate assembly can also be a higher-grade cooling liquid than facility-grade cooling liquid, without limitation.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention. The description of the illustrative embodiments can be read in conjunction with the accompanying figures. Embodiments incorporating teachings of the present disclosure are shown and described with respect to the figures presented herein.

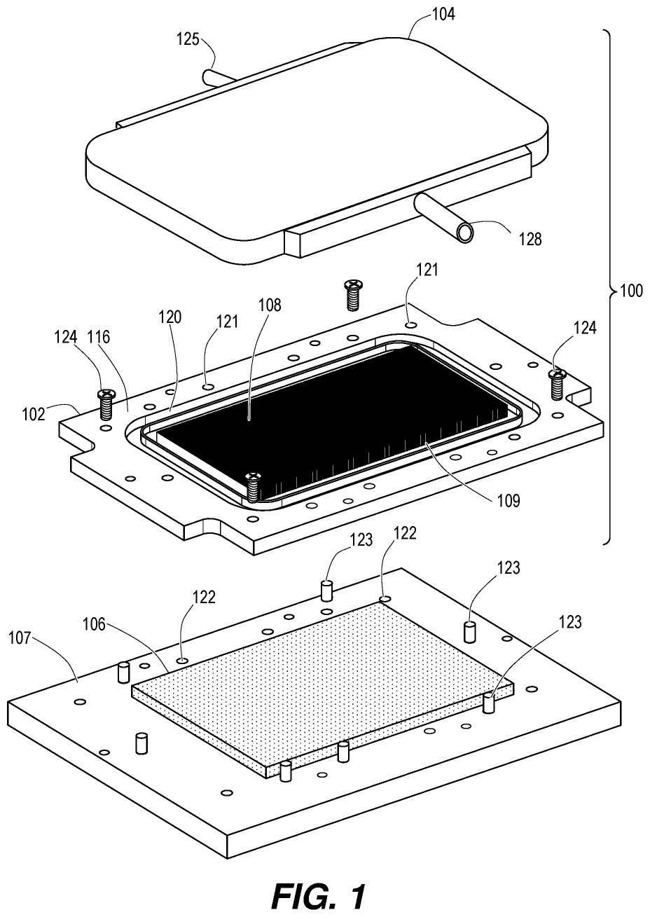

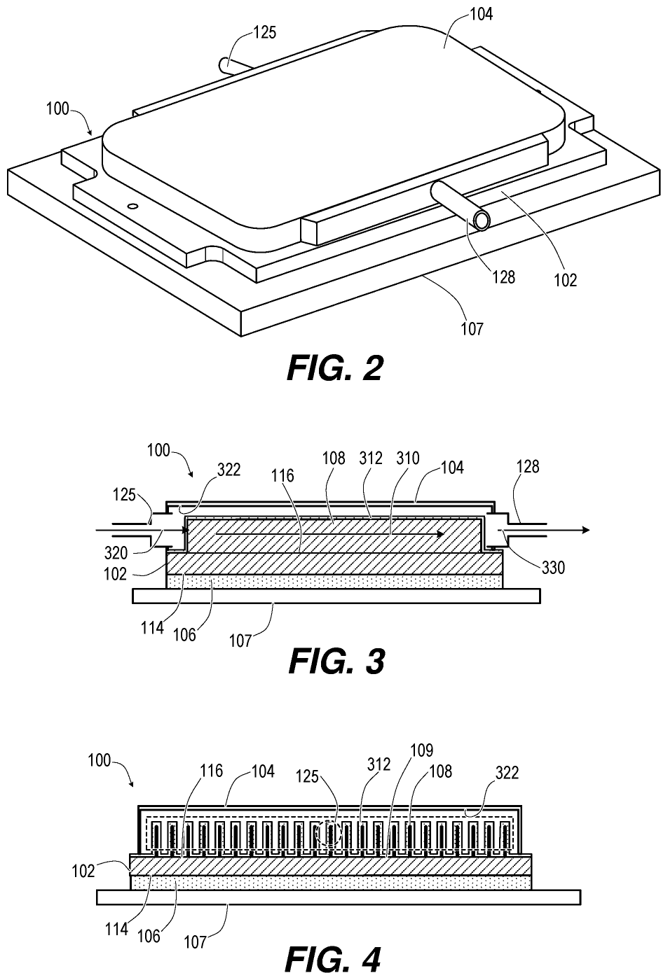

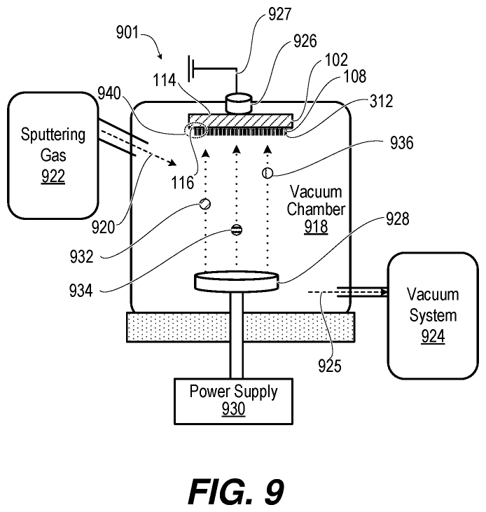

FIG. 1 presents a three-dimensional disassembled view of example cold plate assembly 100 including cold plate 102 and encapsulating lid 104 positioned above heat generating electronic component 106, which receives liquid cooling via the cold plate assembly 100. In an example embodiment, heat generating electronic component 106 is an integrated circuit module, such as a central processing unit (CPU) or graphics processing unit (GPU) on substrate 107 (e.g., a circuit board). In another example embodiment, heat generating electronic component 106 is an electrical power conversion or regulation component. FIG. 2 is a three-dimensional view of the assembled cold plate assembly 100 attached substrate 107 to hold to heat generating electronic component 106 (FIG. 1) into thermal contact with cold plate 102. With particular reference to FIG. 1, example cold plate 102 is formed from a conductive material such as copper that is environmentally hardened, such as in physical vapor deposition (PVD) apparatus described below with regard to FIG. 9, to withstand fouling and/or clogging due to direct use of facility water to provide liquid cooling. Cold plate 102 includes an array of extended fins 108 that present intervening microchannels 109 for liquid passage/flow when the cold plate assembly 100 is assembled and connected to a source of liquid flow. Encapsulating lid includes intake port 125 and exhaust port 128. Additional features of cold plate assembly 100 of FIG. 1 will be described with reference to FIGS. 3 and 4.

FIG. 3 is a side cutaway view of cold plate assembly 100 attached to heat generating electronic component 106 and presenting fin 108 extended in the direction of the cooling liquid flow 310. FIG. 4 is a front cutaway view of cold plate assembly 100 attached to heat generating electronic component 106 and showing protective coating 312 on each of the array of extended fins 108 and intervening microchannels 109 between adjacent fins 108. With reference to FIGS. 3-4 and ongoing reference to FIG. 1, first surface 114 of cold plate 102 provides a heat receiving surface configured to dissipate thermal energy from attached heat generating electronic component 106. With particular reference to FIG. 1, second surface 116 of cold plate 102 is opposite to first surface 114 and provides a heat transferring surface. Second surface 116 is configured with an array of extended fins 108, which may also be referred to as “ribs” or microchannels, to increase convective surface area of the heat transferring surface. Extended fins 108 form or provide microchannels 109 in the conductive material that that are aligned to receive a flow of the cooling liquid, such as water, which contacts and absorbs heat away from the adjacent fins 108. Second surface 116 includes perimeter 120 around the array of extended fins 108 for mounting of encapsulating lid 104. In one or more embodiments, perimeter 120 is recessed into second surface 116 to facilitate sealing attachment of encapsulating lid 104 to cold plate 102. Sealably attaching encapsulating lid 104 to cold plate 102 may include use of one or more of a press-fit interference attachment, an adhesive layer, soldering, brazing, welding, and a fastener attachment.

Through holes 121 pass orthogonally through first and second surfaces 114 (FIG. 3) and 116 of cold plate 102. A subset of holes 122 in substrate 107 receive guide pins 123 that are aligned with corresponding through holes 121 in cold plate 102 to guide assembly of cold plate 102 to substrate 107. Holes 122 in substrate 107 surrounding heat generating component 106 align with other through holes 121 for receiving a respective machine screw 124 to attach cold plate assembly 100 to substrate 107.

According to one additional aspect, cold plate 102 is constructed with flow plate geometry that is designed to prevent flow obstruction by particulate suspended in the liquid coolant. The geometry of the cold plate flow passages (microchannels 109) is designed to promote heat transfer efficiency that is similar to conventional electronic cooling cold plates typically manufactured from bare copper or nickel-plated copper. The array of extended fins 108 may be spaced apart at least 800-microns to facilitate passage of the facility liquid particulates. In one or more embodiments, in manufacturing the cold plate, a geometry of each fin 108 within the array of extended fins 108 may be configured to maintain large hydraulic diameters with greater than 800-micron flow spaces. Unlike conventional devices, cold plate 102 with protective surface coating 312 is tolerant of poorly controlled water quality (including from both chemical contaminants and particulates).

With particular reference to FIGS. 3 and 4, encapsulating lid 104 of cold plate assembly 100 is attachable to second surface 116, encompassing at least the array of extended fins 108 with protective coating 312 to form liquid cooling cavity 322. Encapsulating lid 104 includes intake port 125 positioned to direct incoming liquid flow 320 across second surface 116 through the array of extended fins 108. Encapsulating lid 104 includes exhaust port 128 to direct heated liquid flow 330 exiting the array of extended fins 108 away from cold plate assembly 100. In one or more embodiments, intake port 125 and exhaust port 128 are on opposite sides of encapsulating lid 104 to cooperate in aligning liquid flows 310, 320 and 330. In one or more alternate embodiments, intake port 125 and exhaust port 128 may be adjacently positioned on the same side of encapsulating lid 104. In one or more alternate embodiments, intake port 125 and exhaust port 128 may be orthogonally positioned respectively on two adjacent sides of encapsulating lid 104. Intake port 125, exhaust port 128, and intervening volumetric space of liquid cooling cavity 322 may be configured to maintain a flow velocity of at least 0.7 m/s of liquid impinging the array of extended fins 108 to prevent sedimentation.

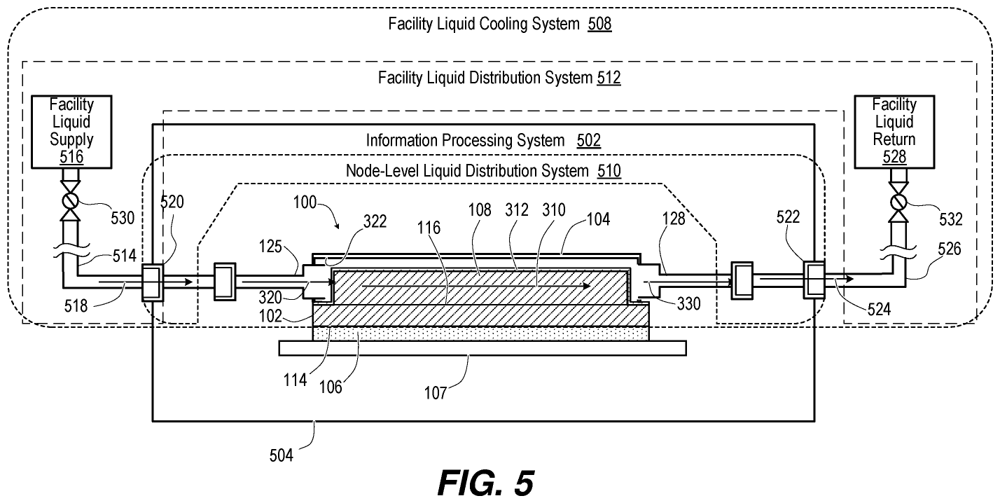

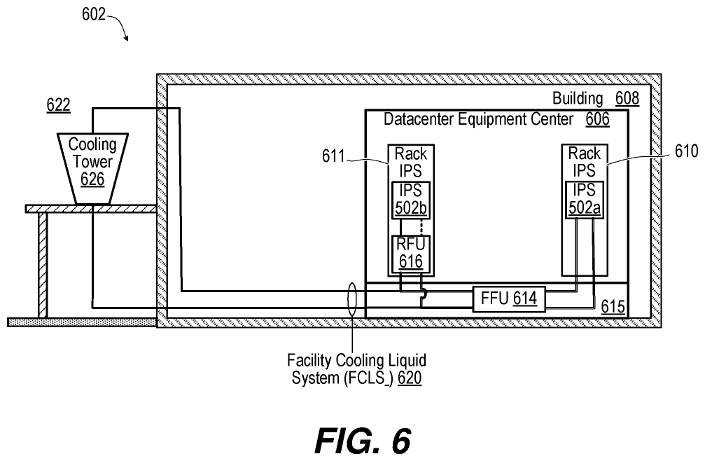

FIG. 5 is a diagram of information processing system (IPS) 502, which may be located in a node of an information processing system rack (see FIG. 6, et seq.). IPS 502 includes one or more heat generating electronic component, such as example heat generating electronic component 106. Liquid cooling system 508 provides cooling liquid flow 310 to cold plate assembly 100 to cool one or more heat generating electronic component 106. Liquid cooling system 508 includes node-level liquid distribution system 510 within node enclosure 504. Liquid cooling system 508 includes rack level and/or data center level liquid distribution system, which are external to IPS 502 and node enclosure 504, and which for simplicity will collectively be referred to as facility liquid distribution system 512 to distinguish from the node-level liquid distribution system 510. Facility liquid distribution system 512 includes supply distribution conduit 514 sealably coupled to facility liquid supply 516 for liquid transfer to provide unheated facility liquid 518, such as water, to intake port 520 of node-level liquid distribution system 510. Exhaust port 522 of node-level liquid distribution system 510 returns heated liquid flow 524 that has passed through cold plate assembly 100. Facility liquid distribution system 512 includes return distribution conduit 526 sealably coupled to exhaust port 522 for liquid transfer to facility liquid return 528. Encapsulating lid 104 is configured to sealably couple for fluid flow via liquid conduits (i.e., node-level liquid distribution system 510 and facility liquid distribution system 512) from facility liquid supply 516 and to a facility liquid return 528. Liquid flow through liquid cooling system 508 may be controlled by a binary or proportional electrically actuated supply valve 530 that is incorporated into supply distribution conduit 514. Alternatively or in addition, liquid flow through liquid cooling system 508 may be controlled by a binary or proportional electrically actuated return valve 532 that is incorporated into return distribution conduit 526.

Accordingly, one aspect of the disclosure provides information processing system 502 that includes heat generating electronic component 106. Information processing system 502 includes cold plate assembly 100 attached to heat generating electronic component 106 via first surface 114 of cold plate 102. Cold plate 102 includes opposed second surface 116 configured with an array of extended fins 108 having exterior surfaces that are coated with coating 312 of at least one of a hydrophobic, a non-conductive, and an anti-corrosive surface treatment. Extended fins 108 support use of unheated facility liquid 518 and provide heat transfer directly to unheated facility liquid 518 without requiring a secondary coolant loop and without causing corrosion or clogging due to facility liquid particulates or chemical contaminants. In one or more embodiments, cold plate assembly 100 further includes encapsulating lid 104 attachable to second surface 116 encompassing at least the array of extended fins 108 to form liquid cooling cavity 322 and comprising intake port 125 and exhaust port 128 for coupling to facility liquid supply 516. In one or more embodiments, cold plate 102 includes a thermally conductive material, and coating 312 on the array of extended fins 108 is both non-conductive and anti-corrosive. In one or more particular embodiments, the array of extended fins 108 are further coated by a hydrophobic layer to prevent scaling and sedimentation due to dissolved calcium carbonate in the facility liquid 518 from facility liquid supply 516.

Aspects of the present disclosure may be applied to an edge mobile datacenter or facility with a single rack IPS. Additionally, aspects of the present disclosure may also be applied to an enterprise datacenter having multiple buildings and rooms with tens, hundreds, or thousands of rack IPSes.

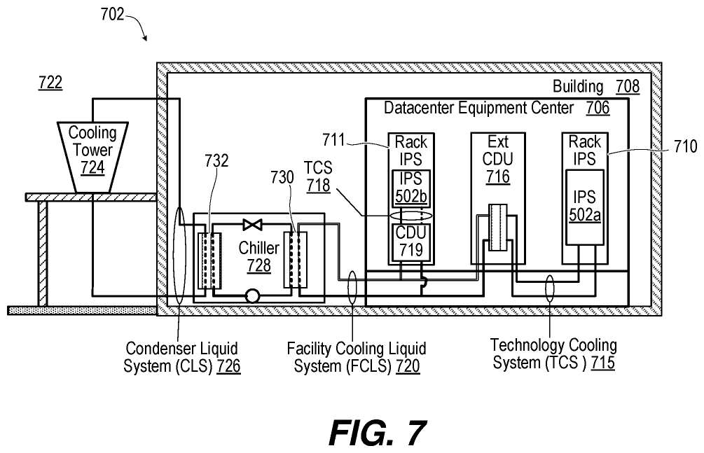

FIG. 6 is a diagram of a first example liquid cooling system that supports a datacenter equipment center with rack-level liquid cooling of heat generating electronic components each utilizing an attached one of the environmentally hardened cold plate assembly of FIG. 1, utilizing one liquid cooling loop for heat exchange, according to one or more embodiments. In the provided example, datacenter equipment center 606 within building 608 includes two rack information processing systems (IPSes) 610 and 611 that have information processing systems (IPSes) 502a and 502b respectively, which receive liquid cooling by respective ones of cold plate assembly 100 (as presented in FIG. 5). In one or more embodiments, rack IPS 610 is supported by floor filtration unit (FFU) 614 in floor space 615 of datacenter equipment center 606. Rack IPS 611 is supported by rack filtration unit (RFU) 616. Liquid cooling system 602 includes a single liquid cooling loop, facility cooling liquid system (FCLS) 620. FCLS 620 circulates facility liquid from cooling tower 626 (or a facility supply) through conduits to the data center and IPSes in rack IPS, and from each cold plate back to cooling tower 626 (or facility return) to dissipate thermal energy to ambient air 622. Utilization of cold plate assembly 100 to provide liquid cooling of heat generating components within the data center (as shown in FIG. 5) eliminates the need for use of purified liquid in a separated rack level technology cooling system 715 (FIG. 7) and the multiple separated cooling loops to provide reliable operation of liquid cooling system 702 (FIG. 7). An existing data center cooling system can be retrofitted with IPSes 610 and 611 that are configured with a plurality of cold plate assembly 100 (FIG. 1) as the mechanism for cooling the heat generating components within the IPS racks, enabling increased reliability for currently maintained purification levels.

FIG. 7 is a diagram of example multi-loop liquid cooling system 702 that supports datacenter equipment center 706 in building 708. Liquid cooling system 702 includes four isolated liquid cooling loops in series, external technology cooling system (TCS) 715 or internal TCS 718, facility cooling liquid system (FCLS) 720, and condenser liquid system 726 that support rack IPSes 710 and 711. Chiller loop 728 is counted as an additional liquid cooling loop. External technology cooling system (TCS) 715 is supported by external cooling distribution unit (CDU) 716 that circulates liquid coolant through IPS 502a via a closed loop. Internal TCS 718 is supported by internal CDU 719 that circulates liquid coolant through IPS 502b of rack IPS 711 also via a closed loop. Internal and external CDUs 716 and 719 transfer thermal energy from internal and external TCSs 715 and 718 to facility cooling liquid such as unpurified water provided by facility cooling system (FCLS) 720. In an example, FCLS 720 may transfer exhaust thermal energy directly into ambient air 722 via cooling tower 724. As depicted in FIG. 7, liquid cooling system 702 may further include condenser liquid system (CLS) 726 that circulates cooling water through cooling tower 724. Liquid cooling system 702 may further include chiller loop 728 (or chiller 728) that stores a thermal buffering quantity of liquid such as water. Chiller 728 circulates the water through first liquid-to-liquid heat exchanger 730 to receive thermal energy from FCLS 720. Chiller 728 circulates the heated water through second liquid-to-liquid heat exchanger 732 to transfer thermal energy to CLS 726. Chiller 728 enables intermittent use of cooling tower 724 while maintaining water in chiller 728 within a temperature range suitable for both FCLS 720 and CLS 726. Utilization of cold plate assembly 100 to provide liquid cooling of heat generating components within the data center (as shown in FIG. 5) eliminates the need for use of purified liquid in a separated rack level technology cooling system 715 and the multiple separated cooling loops to provide reliable operation of liquid cooling system 702. An existing data center cooling system can be retrofitted with IPSes that are configured with a plurality of cold plate assembly 100 as the mechanism for cooling the heat generating components within the IPS racks and replace the more expensive purified cooling liquids within the technology cooling system loop 715, without having issues related to fouling of the cold plates with the switch to utilizing normal, facility rated liquid supply.

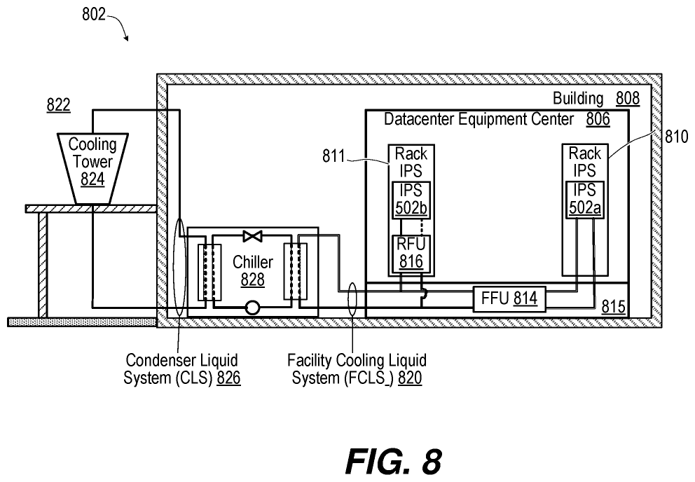

FIG. 8 is a diagram of another example liquid cooling system 802 that incorporates cold plate assembly 100 in IPSes within a datacenter (e.g., FIG. 5), enabling a reduction in a number of isolated liquid cooling loops without degradation of reliability. In the provided example, datacenter equipment center 806 within building 808 includes two rack information processing systems (IPSes) 810 and 811 that have information processing systems (IPSes) 502a and 502b respectively, which receive liquid cooling by respective ones of cold plate assembly 100 (as presented in FIG. 5). In one or more embodiments, rack IPS 810 is supported by floor filtration unit (FFU) 814 in floor space 815 of data center equipment center 806. Rack IPS 811 is supported by rack filtration unit (RFU) 816. In one or more embodiments, liquid cooling system 802 may omit FFU 814 and RFU 816. Because the heat generating electronic component(s) of each of IPS 502a and 502b is configured with an attached cold plate assembly 100 of FIG. 1, highly purified technology cooling liquid is not required. In addition to ultimately exhausting thermal energy into ambient air 822 via cooling tower 824 of CLS 826, liquid cooling system 802 may further include chiller 828 that operates as described above for chiller 728 (FIG. 7) to transfer thermal energy from FCLS 820 to CLS 826.

FIG. 9 presents an example physical vapor deposition (PVD) process by which protective coating 312 can be deposited on a pretreated version of cold plate 102 to generate/manufacture environmentally hardened (or coated) cold plate to protect cold plate 102 from damage, deterioration, and/or clogging due to exposure to facility-grade cooling liquids that can contain corrosive chemical and particulate contaminants. To facilitate use of a facility cooling liquid, such as unpurified water, cold plate 102 is environmentally hardened, such as by applying a coating 312 deposited on cold plate 102 in physical vapor deposition (PVD) apparatus 901. PVD apparatus 901 includes vapor chamber 918 that is filled with sputtering gas 920 received from sputtering gas supply 922 and that is maintained at an appropriate pressure by vacuum system 924 that removes excess gas 925. First surface 114 of cold plate 102 is engaged to substrate holder 926, which is connected to electrical ground 927. Second surface 116 including extended fins 108 with intervening microchannels 109 of cold plate 102 is oriented toward target 928, which includes one or more coating materials to be deposited onto cold plate 102 by PVD. Target 928 is connected to power supply 930 to cause ionization of sputtered atoms 932, 934, and 936, which are attracted by the voltage difference between target 928 and cold plate 102 to that transit across vacuum chamber 918 and be deposited onto cold plate 102 to form coating 312. In an example, first atom 932 represents a hydrophobic material, second atom 934 represents a non-conductive material, and third atom 936 932 represents an anti-corrosive material. Wetted surfaces (i.e., flow passages) of extended fins 108 and other exposed surfaces of cold plate 102 (e.g., the bottom of each microchannel and external edges surrounding the array of fins) are coated with non-conductive, anti-corrosion surface enhancements such as Zirconium Nitride, Titanium Nitride, and other ceramics applied by PVD. In one or more embodiments, the surface may also be coated with a hydrophobic surface treatment to mitigate scale and sedimentation. It is appreciated that while the coating process is shown to be completed by PVD, other similar techniques can be utilized to provide the coating layer(s) on the first surface of cold plate to yield the various physical and chemical enhancements that are described herein. The specific description of PVD as the process is thus not intended to be limiting on the scope of the disclosure.

Facility water, which may contain corrosive chemical and particulate contaminants would be suboptimal for liquid cooling using conventional cold plates. In one or more embodiments, the protective coating applied to the cold plate by the above-described PVD process provides one or more protective characteristics, including: (i) a hydrophobic characteristic to mitigate scaling by calcium carbonate, (ii) an anti-corrosive characteristic to mitigate formation corrosion, and (iii) a non-conductive characteristic to mitigate rusting. Cold plate 102 with coating 312 is designed to resist heat-transfer inhibiting failure modes common to liquid cooling with poorly regulated water quality, namely suspended solid particulates, biological growth potential, and harsh water chemistry conditions, including semi-corrosive mixtures.

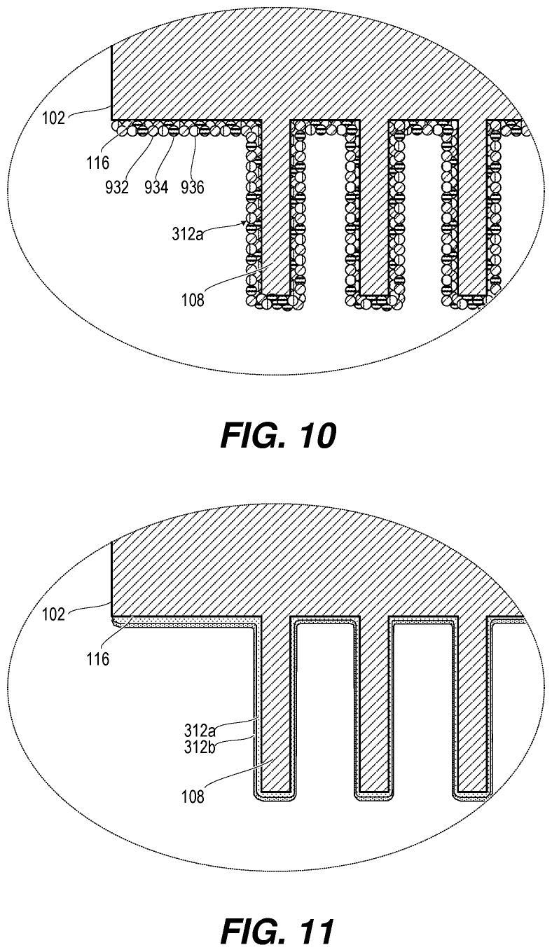

FIG. 10 is a detailed view of a partial portion 940 of cold plate 102 (FIG. 9) having single layer coating 312a deposited by PVD that includes three different and intermixed atoms 932, 934, and 936 respectively having hydrophobic, nonconductive, and anti-corrosion properties. FIG. 11 is a detailed view of portion 940 of coated cold plate 102 (FIG. 9) with dual layer coating 312a, 312b deposited by repeated PVD to provide two or more of the properties.

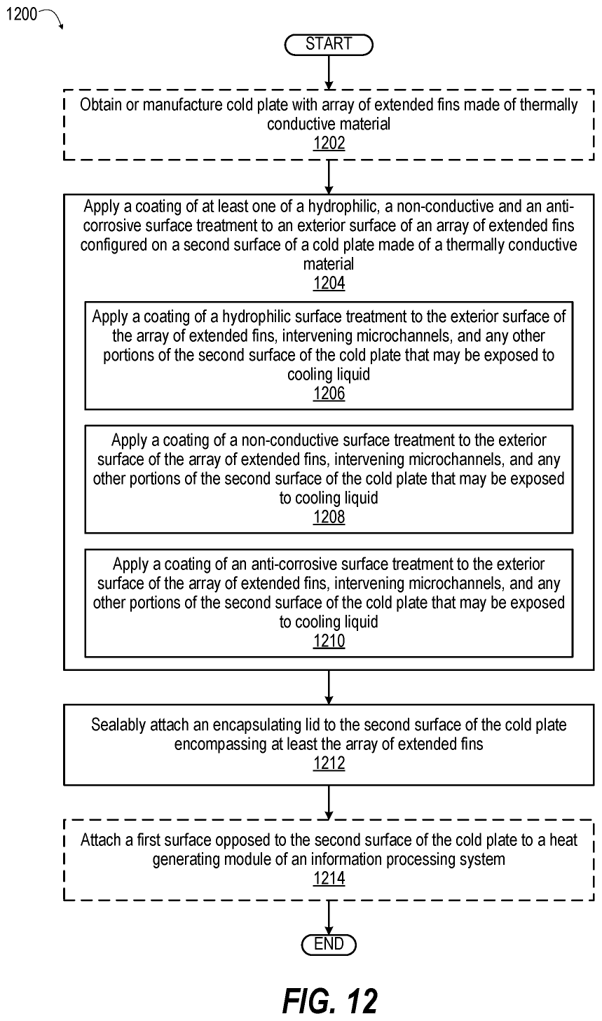

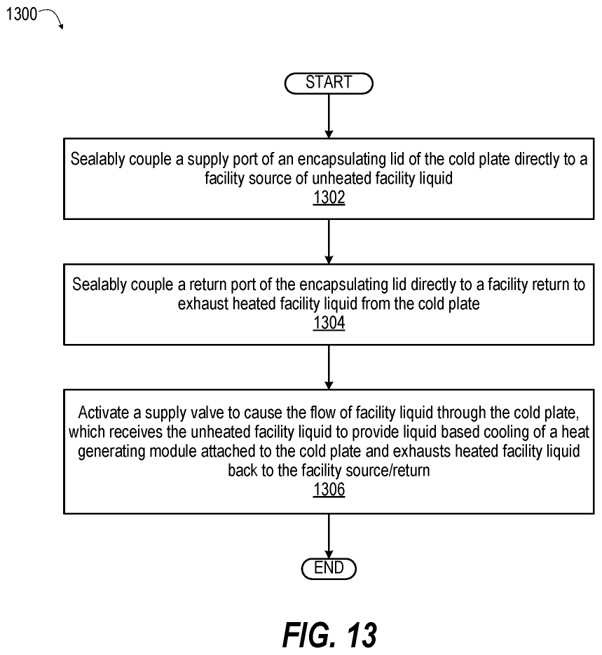

FIG. 12 is a flow diagram presenting method 1200 of manufacturing a cold plate that can utilize facility liquid for liquid cooling of heat generating electronic components without experiencing issues of fouling or clogging. FIG. 13 is a flow diagram presenting method 1300 of using a cold plate having a non-conductive, anti-corrosive (NCAC) coating. The descriptions of method 1200 (FIG. 12) and method 1300 (FIG. 13) are provided with general reference to the specific components illustrated within the preceding FIGS. 1-11. Specific components referenced in method 1200 (FIG. 12) and method 1300 (FIG. 13) may be identical or similar to components of the same name used in describing preceding FIGS. 1-11. In one or more embodiments, an assembly controller of an automated control system or a similar computing device provides the described functionality of method 1200 (FIG. 12) and method 1300 (FIG. 13).

With reference to FIG. 12, in one or more embodiments, method 1200 optionally includes obtaining or manufacturing a cold plate made of a thermally conductive material and having a second exterior surface with an array of extended fins configured on, separated by microchannels (block 1202). Method 1200 includes applying a coating of at least one of a hydrophobic, a non-conductive and an anti-corrosive surface treatment to the second surface of the cold plate (block 1204). In an example, method 1200 includes applying a coating of a hydrophobic surface treatment to the exterior surface of the array of extended fins, intervening microchannels, and any other portions of the second surface of the cold plate that may be exposed to cooling liquid (block 1206). In another example, method 1200 includes applying a coating of a non-conductive surface treatment to the exterior surface of the array of extended fins, intervening microchannels, and any other portions of the second surface of the cold plate that may be exposed to cooling liquid (block 1208). In an additional example, method 1200 includes applying a coating of an anti-corrosive surface treatment to the exterior surface of the array of extended fins, intervening microchannels, and any other portions of the second surface of the cold plate that may be exposed to cooling liquid (block 1210). The coating protects the surface material and thereby allows direct use of facility liquid that may contain corrosive chemical or clogging particulates. The facility liquid provides liquid transfer of heat from a heat generating component to which the cold plate is attached. With the use of environmentally hardened or coated cold plate assembly (100), isolating the facility liquid in a separate cooling loop from a secondary coolant loop that directly cools the heat generating component is not required. The coating avoids or mitigates corrosion and clogging of the cold plate due to facility liquid chemicals and/or particulates. Method 1200 includes sealably attaching an encapsulating lid to the second surface of the cold plate encompassing at least the array of extended fins (block 1212). Sealably attaching the encapsulating lid to the cold plate may include use of one or more of a press-fit interference attachment, adhesive layer, soldering, brazing, welding, and fastener attachment. The encapsulating lid forms a liquid cooling cavity and includes an intake port and an exhaust port for coupling (for supply and return) to a facility liquid source. With the cold plate assembly completed, method 1200 optionally includes attaching a first surface opposed to the second surface of the cold plate to a heat generating electronic component of an information processing system (block 1214). The resulting heat generating electronic component can then be liquid cooled during operation by attaching a first conduit from a liquid supply to the intake port and a second conduit from the exhaust port to the exhaust return port of the liquid return. Then method 1200 ends.

In one or more embodiments, as presented in blocks 1206, 1208, and 1210, applying the coating may include only one of the three characteristics (i.e., hydrophobic, non-conductive, and anti-corrosive) in a coating, two of the three characteristics in the coating, or all three of the characteristics in a coating. In one or more embodiments, as presented in blocks 1206, 1208, and 1210, applying the coating may further includes coating the exterior surface of the array of extended fins with more than one coating of surface treatment, each coating providing one or more of the three characteristics. In one or more embodiments, as presented in block 1206, coating the exterior surface of the array of extended fins includes applying a hydrophobic layer to prevent scaling and sedimentation due to dissolved calcium carbonate in the facility liquid.

In one or more embodiments, the cold plate is manufactured by utilizing copper, as the thermally conductive material. The first surface of the cold plate is a heat receiving surface for attaching to a heat generating electronic component. The second surface of the cold plate is a heat transfer surface. In one or more embodiments, in manufacturing the cold plate, method 1200 further includes configuring the cold plate with the array of extended fins spaced apart at least 800-microns to facilitate passage of the facility liquid particulates. In one or more embodiments, in manufacturing the cold plate, method 1200 further includes configuring a geometry of each fin within the array of extended fins to maintain large hydraulic diameters with greater than 800-micron flow spaces. In one or more embodiments, method 1200 further includes coating the array of extended fins using physical vapor deposition (PVD). In one or more embodiments, method 1200 further includes coating the array of extended fins, via PVD, with one or more ceramics from among a group comprising Zirconium Nitride and Titanium Nitride. In one or more embodiments, in manufacturing the encapsulating lid of the cold plate assembly, method 1200 further includes configuring the intake port, exhaust port, and volumetric space of the liquid cooling cavity to maintain a flow velocity of at least 0.7 m/s of liquid impinging the array of extended fins to prevent sedimentation.

With reference to FIG. 13, method 1300 includes sealably coupling a supply port of an encapsulating lid of the cold plate directly (or indirectly through a supply manifold) to a cooling liquid source of unheated facility liquid (block 1302). Method 1300 includes sealably coupling a return port of the encapsulating lid directly (or indirectly through a return manifold) to a facility return to exhaust heated facility liquid from the cold plate (block 1304). Method 1300 includes activating a supply valve to cause the flow of facility liquid through the cold plate, which receives the unheated facility liquid to provide liquid based cooling of a heat generating electronic component attached to the cold plate and directs the heated facility liquid back to the cooling liquid source or to a cooling liquid return (block 1306). Then method 1300 ends.

In one or more embodiments, the facility liquid can contain at least one of particles and chemical contaminants. The NCAC coating of the extended fins of the cold plate enables direct use of the facility liquid and provide heat transfer directly to the facility liquid without requiring a secondary coolant loop and without causing corrosion or clogging of the cold plate due to facility liquid contaminants or particulates. In one or more embodiments, the cold plate is made from a thermally conductive material, having a first surface attachable to the heat generating electronic component of an information processing system, and having a second surface opposed to the first surface. The second surface is configured with an array of extended fins having exterior surfaces that are coated with at least one of a non-conductive and an anti-corrosive surface treatment, preventing corrosion and/or clogging of the cold plate due to facility liquid contaminants and/or particulates. In one or more embodiments, the array of extended fins of the cold plate are spaced apart at least 800-microns to facilitate passage of the facility liquid particulates.

Aspects of the present innovation are described above with reference to flowchart illustrations and/or block diagrams of methods, apparatus (systems) and computer program products according to embodiments of the innovation. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

As will be appreciated by one skilled in the art, embodiments of the present innovation may be embodied as a system, device, and/or method. Accordingly, embodiments of the present innovation may take the form of an entirely hardware embodiment or an embodiment combining software and hardware embodiments that may all generally be referred to herein as a “component”, “circuit,” “module” or “system.”

While the innovation has been described with reference to exemplary embodiments, it will be understood by those skilled in the art that various changes may be made, and equivalents may be substituted for elements thereof without departing from the scope of the innovation. In addition, many modifications may be made to adapt a particular system, device, or component thereof to the teachings of the innovation without departing from the essential scope thereof. Therefore, it is intended that the innovation not be limited to the particular embodiments disclosed for carrying out this innovation, but that the innovation will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the innovation. As used herein, the singular forms “a”, “an” and “the” are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present innovation has been presented for purposes of illustration and description but is not intended to be exhaustive or limited to the innovation in the form disclosed. Many modifications and variations will be apparent to those of ordinary skill in the art without departing from the scope and spirit of the innovation. The embodiments were chosen and described in order to best explain the principles of the innovation and the practical application, and to enable others of ordinary skill in the art to understand the innovation for various embodiments with various modifications as are suited to the particular use contemplated.

What is claimed is:

1. A cold plate assembly comprising:
a cold plate comprising a thermally conductive material, having a first surface attachable to a heat generating electronic component of a data processing system, and having a second surface opposed to the first surface and configured with an array of extended fins having exterior surfaces that are coated with at least one of a hydrophobic, a non-conductive, and an anti-corrosive surface treatment, the extended fins supporting use of facility-grade cooling liquid and providing heat transfer directly to the cooling liquid without requiring a secondary coolant loop and without causing corrosion or clogging due to cooling liquid particulates or chemical contaminants; and
an encapsulating lid attachable to the second surface encompassing at least the array of extended fins to form a liquid cooling cavity and comprising an intake port and an exhaust port for coupling to a cooling liquid supply.

2. The cold plate assembly of claim 1, wherein the coating on the array of extended fins is both non-conductive and anti-corrosive.

3. The cold plate assembly of claim 1, wherein the array of extended fins are further coated by a hydrophobic layer to prevent scaling and sedimentation due to dissolved calcium carbonate in the cooling liquid.

4. The cold plate assembly of claim 1, wherein the thermally conductive material of the cold plate comprises copper, the first surface is a heat receiving surface, and the second surface is a heat transfer surface.

5. The cold plate assembly of claim 1, wherein the array of extended fins are spaced apart at least 800-microns to facilitate passage of the cooling liquid particulates.

6. The cold plate assembly of claim 1, wherein the intake port, exhaust port, and volumetric space of the liquid cooling cavity are designed to maintain a flow velocity of at least 0.7 m/s of liquid impinging the array of extended fins to prevent sedimentation.

7. The cold plate assembly of claim 1, wherein a geometry of each fin within the array of extended fins is designed to maintain large hydraulic diameters with greater than 800-micron flow spaces.

8. The cold plate assembly of claim 1, wherein the array of extended fins are coated using physical vapor deposition (PVD) to provide the non-conductive treatment and the anti-corrosive surface treatment.

9. The cold plate assembly of claim 8, wherein the array of extended fins are coated, via PVD, with one or more ceramics from among a group comprising Zirconium Nitride and Titanium Nitride.

10. A method of manufacturing a cold plate that uses facility liquid for liquid cooling of heat generating electronic components, the method comprising:
applying a coating of at least one of a hydrophobic, a non-conductive and an anti-corrosive surface treatment to an exterior surface of an array of extended fins configured on a second surface of a cold plate comprising a thermally conductive material, the coating supporting direct use of facility-grade cooling liquid to provide liquid transfer of heat by the facility liquid from a heat generating component to which an opposing first surface the cold plate is attached without requiring a secondary coolant loop and without causing corrosion or clogging due to cooling liquid particulates.

11. The method of claim 10, further comprising:
sealably attaching an encapsulating lid to the second surface of the cold plate encompassing at least the array of extended fins, the encapsulating lid forming a liquid cooling cavity and comprising an intake port and an exhaust port for coupling to a facility liquid source.

12. The method of claim 11, wherein the intake port, exhaust port, and volumetric space of the liquid cooling cavity are designed to maintain a flow velocity of at least 0.7 m/s of liquid impinging the array of extended fins to prevent sedimentation.

13. The method of claim 11, further comprising attaching a first surface, opposed to the second surface of the cold plate, to a heat generating electronic component of an information processing system.

14. The method of claim 10, wherein applying the coating further comprises coating the exterior surface of the array of extended fins with a surface treatment that is both non-conductive and anti-corrosive.

15. The method of claim 10, further comprising coating the exterior surface of the array of extended fins with a hydrophobic layer to prevent scaling and sedimentation due to dissolved calcium carbonate in the cooling liquid.

16. The method of claim 10, further comprising manufacturing the cold plate from the thermally conductive material comprising copper, the first surface being a heat receiving surface for attaching to a heat generating electronic component, and the second surface being a heat transfer surface.

17. The method of claim 16, further comprising configuring the cold plate with the array of extended fins spaced apart at least 800-microns to facilitate passage of the cooling liquid particulates.

18. The method of claim 17, wherein a geometry of each fin within the array of extended fins is designed to maintain large hydraulic diameters with greater than 800-micron flow spaces.

19. The method of claim 10, wherein applying the coating further comprises coating the array of extended fins using physical vapor deposition (PVD).

20. The method of claim 19, further comprising coating the array of extended fins, via PVD, with one or more ceramics from among a group comprising Zirconium Nitride and Titanium Nitride.

21. A method for using a cold plate having a non-conductive, anti-corrosive (NCAC) coating, the method comprising:
sealably coupling a supply port of an encapsulating lid of the cold plate directly to a facility source of unheated facility liquid;
sealably coupling a return port of the encapsulating lid directly to a facility return to exhaust heated facility liquid from the cold plate; and
activating a supply valve to cause a flow of facility liquid through the cold plate, which receives the unheated facility liquid to provide liquid based cooling of a heat generating electronic component attached to the cold plate and exhausts heated facility liquid back to the facility source.

22. The method of claim 21, wherein:
the facility liquid contains at least one of particles and chemical contaminants; and
the NCAC coating of extended fins of the cold plate enables direct use of the facility liquid and provide heat transfer directly to the facility liquid without requiring a secondary coolant loop and without causing corrosion or clogging of the cold plate due to facility liquid particulates.

23. The method of claim 21, wherein the cold plate comprises a thermally conductive material, having a first surface attachable to the heat generating electronic component of a data processing system, and having a second surface opposed to the first surface and configured with an array of extended fins having exterior surfaces that are coated with at least one of a non-conductive and an anti-corrosive surface treatment, preventing corrosion or clogging of the cold plate due to facility liquid particulates.

24. The method of claim 23, wherein the array of extended fins of the cold plate are spaced apart at least 800-microns to facilitate passage of the facility liquid particulates.

25. The method of claim 23, wherein the coating on the array of extended fins is deposited using physical vapor deposition (PVD) and comprises one or more ceramics from among a group comprising Zirconium Nitride and Titanium Nitride.

26. A liquid cooling system comprising:
a cold plate assembly comprising:
a cold plate comprising a thermally conductive material, having a first surface attachable to a heat generating electronic component of an information processing system, and having a second surface opposed to the first surface and configured with an array of extended fins having exterior surfaces that are coated with at least one of a hydrophobic, a non-conductive and an anti-corrosive surface treatment, the extended fins supporting use of facility-grade cooling liquid and providing heat transfer directly to the cooling liquid without requiring a secondary coolant loop and without causing corrosion or clogging due to cooling liquid particulates; and
an encapsulating lid attachable to a perimeter of the second surface encompassing at least the array of extended fins to form a liquid cooling cavity and comprising an intake port and an exhaust port for coupling to a cooling liquid supply; and
an open-loop liquid distribution system sealably connected to and in fluid communication between the intake port of the cold plate and a cooling liquid source to receive unheated facility liquid and between the exhaust port of the cold plate and a cooling liquid return to exhaust heated facility liquid to the cooling liquid return.

27. The liquid cooling system of claim 26, wherein the array of extended fins are non-conductive, anti-corrosive (NCAC) extended fins having exterior surfaces that are coated with a surface treatment that is both non-conductive and anti-corrosive.

28. The liquid cooling system of claim 26, wherein the array of extended fins are further coated by a hydrophobic layer to prevent scaling and sedimentation due to dissolved calcium carbonate in the facility liquid.

29. The liquid cooling system of claim 26, wherein the thermally conductive material of the cold plate comprises copper, the first surface is a heat receiving surface, and the second surface is a heat transfer surface.

30. The liquid cooling system of claim 26, wherein the array of extended fins are spaced apart at least 800-microns to facilitate passage of the cooling liquid particulates.

31. The liquid cooling system of claim 26, wherein the intake port, exhaust port, and volumetric space of the liquid cooling cavity are designed to maintain a flow velocity of at least 0.7 m/s of liquid impinging the array of extended fins to prevent sedimentation.

32. The liquid cooling system of claim 26, wherein a geometry of each fin within the array of NCAC extended fins is designed to maintain large hydraulic diameters with greater than 800-micron flow spaces.

33. The liquid cooling system of claim 26, wherein the array of extended fins are coated using physical vapor deposition (PVD) to provide the non-conductive treatment and the anti-corrosive surface treatment.

34. The liquid cooling system of claim 33, wherein the array of extended fins are coated, via PVD, with one or more ceramics from among a group comprising Zirconium Nitride and Titanium Nitride.

35. The liquid cooling system of claim 26, further comprising at least one electrically actuated valve in fluid communication between the open-loop distribution system and the cold plate assembly to regulate fluid flow through the liquid cooling cavity.

36. The liquid cooling system of claim 26, wherein the heat generating electronic component comprises an integrated circuit module.

37. An information processing system comprising:
a heat generating electronic component; and
a cold plate assembly attached to the heat generating electronic component via a first surface of a cold plate comprising an opposed second surface configured with an array of extended fins having exterior surfaces that are coated with at least one of a hydrophobic, a non-conductive, and an anti-corrosive surface treatment, the extended fins supporting use of facility-grade cooling liquid and providing heat transfer directly to the cooling liquid without requiring a secondary coolant loop and without causing corrosion or clogging due to cooling liquid particulates or chemical contaminants.

38. The information processing system of claim 37, wherein the cold plate assembly further comprises:
an encapsulating lid attachable to the second surface encompassing at least the array of extended fins to form a liquid cooling cavity and comprising an intake port and an exhaust port for coupling to a cooling liquid supply.

39. The information processing system of claim 37, wherein the cold plate comprises a thermally conductive material and the coating on the array of extended fins is both non-conductive and anti-corrosive.

40. The information processing system of claim 39, wherein the array of extended fins is further coated by a hydrophobic layer to prevent scaling and sedimentation due to dissolved calcium carbonate in the cooling liquid.
